(19) United States
(12) Patent Application Publication
(10) Pub. No.: US 2025/0120290 A1
(43) Pub. Date: Apr. 10, 2025

(54) Display Apparatus with Moisture Barrier Structure and Method for Manufacturing the Display Apparatus

(71) Applicant: LG Display Co., Ltd., Seoul (KR)

(72) Inventors: Yubeen Lim, Paju-si (KR); Soyang Choi, Paju-si (KR); Hanseok Lee, Paju-si (KR); JungJune Kim, Paju-si (KR)

(21) Appl. No.: 18/904,592

(22) Filed: Oct. 2, 2024

(30) Foreign Application Priority Data
Oct. 10, 2023 (KR) 10-2023-0134199

(51) Int. Cl. H10K 59/80; H10K 59/12; H10K 59/65; H10K 102/00

(52) U.S. Cl. CPC H10K 59/8731; H10K 59/1201; H10K 59/65; H10K 2102/351

(57) ABSTRACT

A display apparatus with a moisture barrier structure and a method for manufacturing the display apparatus are disclosed. The display apparatus includes a first thin film transistor on a substrate, a separation layer disposed on the first thin film transistor and including an organic material, an inorganic insulating layer on the separation layer, a buffer layer on the inorganic insulating layer, a second thin film transistor on the buffer layer, and a display element connected to any one of the first thin film transistor and the second thin film transistor, wherein the separation layer has a recess, the recess has an opening in a direction toward the inorganic insulating layer, and the inorganic insulating layer is not disposed in the opening.

### CROSS-REFERENCE TO RELATED APPLICATION

This application claims the benefit and priority of the Republic of Korea Patent Application No. 10-2023-0134199 filed on Oct. 10, 2023, which is hereby incorporated by reference in its entirety.

### TECHNICAL FIELD

The present disclosure relates to a display apparatus that has a moisture barrier structure and can effectively block moisture penetration, and a method of manufacturing the same.

### DESCRIPTION OF THE RELATED ART

Recently, as a display apparatus, a flat display apparatus or a flexible display apparatus are widely used. Among the display apparatus, an organic light emitting display apparatus, which is a self-emitting display apparatus, has the advantages of a wide viewing angle, excellent contrast characteristics, and fast response characteristics. In addition, the organic light emitting display apparatus has an advantage of being easily applied as flexible display apparatus.

The organic light emitting display apparatus includes a plurality of organic light emitting diodes. The organic light emitting diode includes an anode electrode, a light emitting layer, and a cathode electrode. When a high potential voltage is applied to the anode electrode and a low potential voltage is applied to the cathode electrode, holes from the anode electrode and electrons from the cathode electrode, respectively, move to the light emitting layer. When holes and electrons combine in the light emitting layer, excitons are formed during the excitation process, and light is generated due to the energy from the excitons. The organic light emitting display apparatus displays images by electrically controlling the amount of light generated from the light emitting layer of a plurality of organic light emitting diodes.

The organic light emitting display apparatus have various advantages, but have the disadvantage of being vulnerable to moisture and oxygen. To solve this problem, methods for blocking moisture and oxygen penetrating into the organic light emitting display apparatus from the outside are being studied. In particular, when a through hole is located inside the display area, moisture and oxygen can easily penetrate through the through hole, and thus, it is necessary to block moisture and oxygen penetrating into the organic light emitting display apparatus from around the through hole.

### SUMMARY

The present disclosure has been made in view of the above problems and an aspect of an embodiment of the present disclosure is to provide a display apparatus that has a moisture barrier structure and can effectively block moisture penetration.

An aspect of another embodiment of the present disclosure is to provide a display apparatus that can effectively block moisture penetration by having a moisture barrier structure disposed around the through-holes, even though a through hole for placing various components, for example, a camera module or an optical sensor, are provided in the display area.

An aspect of another embodiment of the present disclosure is to provide a display apparatus that can effectively block moisture penetration by having a moisture barrier structure disposed at the edge of the display panel.

An aspect of another embodiment of the present disclosure is to provide a method of manufacturing a display apparatus having a moisture barrier structure.

In accordance with an aspect of the present disclosure, the above and other objects can be accomplished by the provision of a display apparatus comprising a first thin film transistor on a substrate, a separation layer disposed on the first thin film transistor and including an organic material, an inorganic insulating layer on the separation layer, a buffer layer on the inorganic insulating layer, a second thin film transistor on the buffer layer, and a display element connected to any one of the first thin film transistor and the second thin film transistor, wherein the separation layer has a recess, and wherein the recess has an opening in a direction toward the inorganic insulating layer, and the inorganic insulating layer is not disposed in the opening.

The separation layer may have a higher etch rate than the inorganic insulating layer.

A width of the recess may be greater than a width of the opening. Here, the width of the recess is a width measured at a mid-height of the recess, and the width of the opening is a width measured at a bottom of the inorganic insulating layer.

The width of the recess may be more than twice the width of the opening.

The separation layer may have two or more recesses.

The buffer layer may be disposed on a side wall of the recess.

The display element may include an organic light emitting layer, and wherein the organic light emitting layer loses continuity in the recess.

The separation layer may have a thickness of 1 to 4 μm.

The substrate may have a through hole.

The display apparatus may further comprise an optical element disposed overlapping with a through hole formed in the substrate. The first thin film transistor, the second thin film transistor, and the display element are not disposed in the through hole, and wherein the recess surrounds the through hole.

The optical element may include at least one of a camera, an infrared sensor, a proximity sensor, an illumination sensor, and a fingerprint sensor.

The display apparatus may further comprise an encapsulation layer on the display element, wherein the encapsulation layer comprises a first inorganic encapsulation layer, an organic encapsulation layer on the first inorganic encapsulation layer and a second inorganic encapsulation layer on the organic encapsulation layer, wherein the first inorganic encapsulation layer is disposed on the buffer layer disposed on a side wall of the recess.

The recess may be disposed along an edge of the substrate.

Another embodiment of the present disclosure provides method of manufacturing a display apparatus comprising, forming a first thin film transistor on a substrate, forming a separation layer containing an organic material on the first thin film transistor, forming an inorganic insulating layer on the separation layer, removing a portion of the inorganic insulating layer and a portion of the separation layer to form a hole passing through the inorganic insulating layer and the separation layer, expanding the hole formed in the separation layer to form a recess in the separation layer, forming a buffer layer on the inorganic insulating layer, forming a second thin film transistor on the buffer layer, and forming a display element connected to any one of the first thin film transistor and the second thin film transistor.

An etch rate of the separation layer may be greater than an etch rate of the inorganic insulating layer.

Forming the hole passing through the inorganic insulating layer and the separation layer may further include forming a contact hole connecting the first thin film transistor and the second thin film transistor.

The method of manufacturing the display apparatus may further comprise forming a first bridge electrode on the inorganic insulating layer, wherein the first bridge electrode is connected to the first thin film transistor through the contact hole.

In forming the buffer layer, a buffer layer forming material may be disposed on a side wall of the recess.

Forming the display element may include forming an organic light emitting layer, and wherein the organic light emitting layer loses continuity in the recess.

The hole passing through the inorganic insulating layer and the separation layer may be formed along an edge of the substrate, so that the recess is formed along the edge of the substrate.

### Technical Effects of the Disclosure

According to an embodiment of the present disclosure, the display panel of the display apparatus is provided with a moisture barrier structure, thereby preventing or at least reducing moisture or oxygen from entering the display panel from the outside. As a result, display elements disposed on the display panel, especially organic light emitting elements, can be protected from moisture or oxygen.

Meanwhile, among the components of an organic light emitting device, the organic light emitting layer is very vulnerable to moisture or oxygen. Therefore, according to an embodiment of the present disclosure, when the display panel of the display apparatus is provided with a moisture barrier structure, moisture or oxygen from the outside is prevented or at least reduced from flowing into the display panel, and the organic light emitting layer of the organic light emitting device can be protected from moisture or oxygen. As a result, the lifespan of the organic light emitting device can be extended, and thus the lifespan of the display panel can also be extended.

According to another embodiment of the present disclosure, even if a through hole for arranging various components or optical elements, for example, a camera module or an optical sensor, is provided in the display area, a moisture barrier structure is disposed around the through hole, so that the external moisture or oxygen can be prevented or at least reduced from flowing into the display panel of the display apparatus.

In addition, according to another embodiment of the present disclosure, a moisture barrier structure is disposed at the edge of the display panel to prevent moisture or oxygen from entering the display panel of the display apparatus from the outside.

In addition to the above-mentioned effects, other features and advantages of the present disclosure are described below, and can be clearly understood by those skilled in the art from the descriptions.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings.

FIG. 1 is a schematic diagram of a display apparatus according to an embodiment of the present disclosure.

FIG. 2 is a circuit diagram of a pixel of FIG. 1 according to an embodiment of the present disclosure.

FIG. 3 is a schematic diagram of an embodiment of a display panel.

FIG. 4 is an enlarged plan view of a portion indicated by HA in FIG. 3 according to an embodiment of the present disclosure.

FIG. 5 is a cross-sectional view along a line I-I′ of FIG. 4 according to an embodiment of the present disclosure.

FIG. 6 is a partial enlarged view of a dam portion and recess of FIG. 5 according to an embodiment of the present disclosure.

FIG. 7 is a partial cross-sectional view of a display apparatus according to another embodiment of the present disclosure.

FIG. 8 is a schematic diagram of a display panel of a display apparatus according to another embodiment of the present disclosure.

FIG. 9 is a cross-sectional view along a line II-II′ of FIG. 8 according to an embodiment of the present disclosure.

FIG. 10 is a circuit diagram of a pixel of a display apparatus according to another embodiment of the present disclosure.

FIG. 11 is a circuit diagram of a pixel of a display apparatus according to another embodiment of the present disclosure.

FIGS. 12A to 12G are schematic diagrams of a manufacturing process of a display apparatus according to an embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise’, ‘have’, and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜’, ‘above˜’, ‘below˜’, and ‘next to˜’, one or more portions may be arranged between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first”, “second”, etc. may be used herein to describe various elements, these elements should not be limited by these terms. These terms are only used to partition one element from another. For example, a first element could be termed a second element, and, similarly, a second element could be termed a first element, without departing from the scope of the present invention.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

In the drawings, the same or similar elements are denoted by the same reference numerals even though they are depicted in different drawings.

Hereinafter, examples or embodiments of the present disclosure will be described with reference to the attached drawings. The scale of the components shown in the drawings may be different from the actual scale for convenience of description, and is therefore not limited to the scale shown in the drawings.

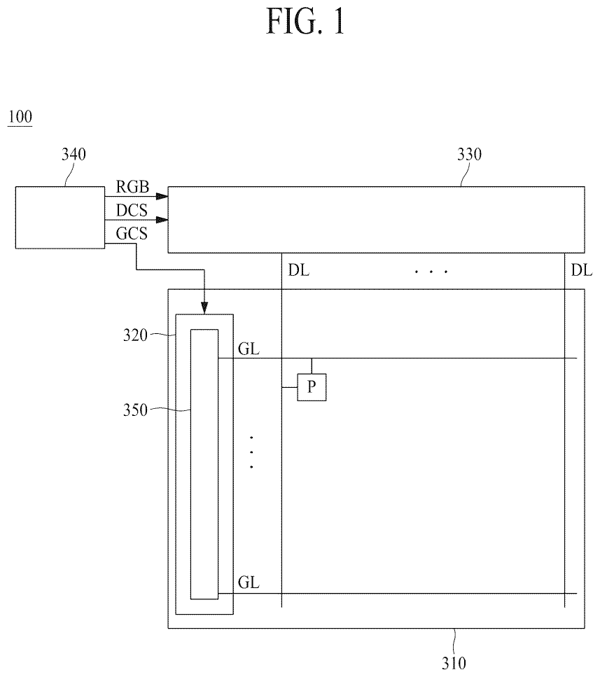

FIG. 1 is a schematic diagram of a display apparatus 100 according to an embodiment of the present disclosure.

As shown in FIG. 1, the display apparatus 100 according to an embodiment of the present disclosure may include a display panel 310, a gate driver 320, a data driver 330, and a controller 340.

Gate lines GL and data lines DL are disposed in the display panel 310, and pixels P are disposed at intersections of the gate lines GL and data lines DL. Images are displayed by driving pixels P.

The controller 340 controls the gate driver 320 and data driver 330.

The controller 340 uses, for example, a signal supplied from an external system (not shown) to generate a gate control signal GCS to control the gate driver 320 and a data control signal DCS to control the data driver 330. In addition, the controller 340 samples input image data input from an external system, realigns it, and supplies the realigned digital image data RGB to the data driver 330.

The gate control signal GCS includes a gate start pulse GSP, gate shift clock GSC, gate output enable signal GOE, start signal Vst, and gate clock GCLK. In addition, the gate control signal GCS may include control signals for controlling the shift register 350.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

The gate driver 320 may include a shift register 350.

The shift register 350 sequentially supplies gate pulses to the gate lines GL for one frame using a start signal and gate clock transmitted from the controller 340. In this case, one frame means a time period during which one image is output through the display panel 310. The gate pulse has a turn-on voltage that can turn on the switching element (thin film transistor) disposed in the pixel P.

In addition, the shift register 350 supplies a gate-off signal capable of turning off the switching element to the gate line GL during the remaining period of the one frame in which the gate pulse is not supplied. Hereinafter, the gate pulse and gate-off signal are collectively referred to as a scan signal (SS or Scan).

According to an embodiment of the present disclosure, the gate driver 320 may be mounted in the display panel 310. In this way, the structure in which the gate driver 320 is directly mounted in the display panel 310 is called a gate in panel GIP structure.

The gate driver 320 may include a plurality of thin film transistors. A plurality of thin film transistors may be disposed in the shift register 350.

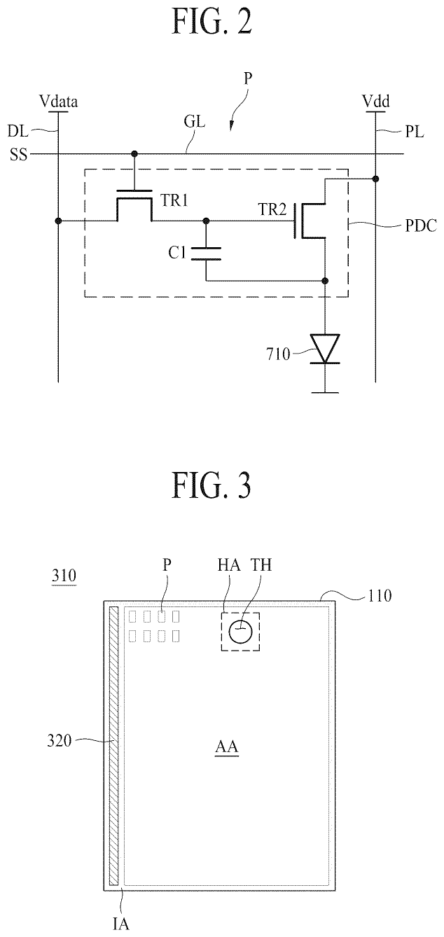

FIG. 2 is a circuit diagram of a pixel P of FIG. 1 according to an embodiment of the present disclosure.

The circuit diagram of FIG. 2 is an equivalent circuit diagram for a pixel P of the display apparatus 100 including an organic light emitting diode OLED as the display element 710. The pixel P includes a display element 710 and a pixel driving circuit PDC that drives the display element 710.

Referring to FIG. 2, the display apparatus 100 according to an embodiment of the present disclosure includes a pixel driving circuit PDC and a display element 710 connected to the pixel driving circuit PDC. The pixel driving circuit PDC may include a first thin film transistor TR1 and a second thin film transistor TR2.

FIG. 2 illustrates a pixel driving circuit PDC in which the first thin film transistor TR1 is a switching transistor and the second thin film transistor TR2 is a driving transistor.

The first thin film transistor TR1 is connected to the gate line GL and the data line DL, and is turned on or turned off by the scan signal SS supplied through the gate line GL.

The data line DL provides a data voltage Vdata to the pixel driving circuit PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

When the first thin film transistor TR1 is turned on by the scan signal SS applied from the gate driver 320 through the gate line GL, the data voltage Vdata supplied from the data line DL is supplied to the gate electrode of the second thin film transistor TR2 connected to the display element 710. The data voltage Vdata is charged in the storage capacitor C1 formed between the gate electrode and the source electrode of the second thin film transistor TR2. The capacitor C1 of FIG. 2 is a storage capacitor formed between the gate electrode and the source electrode of the second thin film transistor TR2.

Referring to FIG. 2, the gate electrode of the second thin film transistor TR2 is connected to the drain electrode of the first thin film transistor TR1. Accordingly, the capacitor C1 of FIG. 2 may be referred to as being formed between the drain electrode of the first thin film transistor TR1 and the source electrode of the second thin film transistor TR2.

The amount of current supplied to the organic light emitting diode OLED, which is the display element 710, through the second thin film transistor TR2 is controlled according to the data voltage Vdata, whereby a gray scale of light emitted from the display element 710 may be controlled.

FIG. 3 is a schematic diagram of an embodiment of the display panel 310. FIG. 3 shows a display panel 310 applied to the display apparatus 100, for example, an organic light emitting panel. The display apparatus 100 of FIG. 1, which includes an organic light emitting panel as the display panel 310, may be referred to as an organic light emitting display apparatus.

Referring to FIG. 3, the display panel 310 includes a substrate 110 and pixels P on the substrate 110.

A glass substrate or a plastic substrate may be used as the substrate 110. The substrate 110 may include a display area AA and a non-display area IA.

The display area AA is an area where an image is displayed and may be referred to as a pixel array area, active area, pixel array unit, display area, or screen. The display area AA includes a pixel P. A plurality of pixels P may be arranged in the display area AA.

A plurality of pixels P may be arranged along each of a first direction and a second direction crossing the first direction. For example, the first direction may be referred to as a first longitudinal direction or a horizontal direction of the substrate 110. The second direction may be referred to as a second longitudinal direction or a vertical direction of the substrate 110.

The pixel P can be said to be a unit area where light is actually emitted.

The non-display area IA is an area where images are not displayed. For example, the non-display area IA may be arranged around the display area AA. The non-display area IA may be configured to surround the display area AA.

The non-display area IA may include at least one of a peripheral circuit area, a signal supply area, an inactive area, and a bezel area. The non-display area IA may be referred to as, for example, a peripheral area, a peripheral circuit area, a signal supply area, an inactive area, or a bezel area.

The display panel 310 may further include a peripheral circuit portion disposed in the non-display area IA. The peripheral circuit portion may include a gate driver 320 connected to a plurality of pixels P. FIGS. 1 and 3 illustrate a configuration in which the gate driver 320 is disposed on the substrate 110 as the peripheral circuit portion.

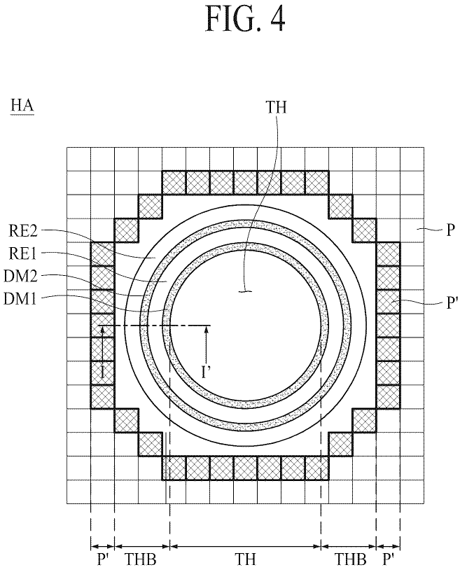

FIG. 4 is an enlarged plan view of the portion indicated by HA in FIG. 3 according to an embodiment of the present disclosure.

FIG. 4 is an enlarged plan view showing a through hole TH and its surrounding area disposed in the display area AA of the display apparatus 100 according to an embodiment of the present disclosure.

According to an embodiment of the present disclosure, as shown in FIG. 4, a through hole TH may be disposed in the display area AA. Pixels P may be disposed around the through hole TH. Among the pixels P, a series of pixels P arranged closest to the through hole TH can be defined as adjacent pixels P′ as indicated in FIG. 4. The area between adjacent pixels P′ and the through hole TH can be defined as a hole boundary portion THB.

According to an embodiment of the present disclosure, a moisture barrier structure is disposed at the hole boundary portion THB. Therefore, according to an embodiment of the present disclosure, the hole boundary portion THB may be referred to as a moisture barrier area.

A dam portion DM1, DM2 and a recess RE1, RE2 may be disposed at the hole boundary portion THB.

The dam portion DM1, DM2 may include a first dam DM1 and a second dam DM2. In detail, referring to FIG. 4, the first dam DM1 and the second dam DM2 may be disposed between the through hole TH and the adjacent pixel P′.

The first dam DM1 may have a closed curve shape surrounding the through hole TH. The first dam DM1 may have a closed curve shape corresponding to the shape of the through hole TH, but may also have a closed curve shape different from the shape of the through hole TH. In FIG. 4, for example, the first dam DM1 is shown to have a closed curve shape that has the same shape as the through hole TH and has a different size. Referring to FIG. 4, the first dam DM1 and the through hole TH have a concentric circular shape, and the area of the through hole TH may be defined by the first dam DM1. According to an embodiment of the present disclosure, the sidewall of the through hole TH that defines the area of the through hole TH may be the first dam DM1.

According to an embodiment of the present disclosure, the second dam DM2 may be disposed between the first dam DM1 and the adjacent pixel P′.

The second dam DM2 is spaced apart from the first dam DM1 and may have a closed curve shape surrounding the first dam DM1. The second dam DM2 may have a closed curve shape corresponding to the shape of the first dam DM1, but may also have a closed curve shape different from the shape of the through hole TH. Referring to FIG. 4, the second dam DM2 and the first dam DM1 may have a concentric circular shape.

A recess RE1, RE2 may be disposed between the through hole TH and the adjacent pixel P′. The recess RE1, RE2 may have a closed curve shape that corresponds to the shape of the through hole TH and surrounds the through hole TH. The recess RE1, RE2 may have a different closed curve shape from the shape of the through hole TH, or may have a same closed curve shape but a different size.

The recess RE1, RE2 may include a first recess RE1 and a second recess RE2. Referring to FIG. 4, the first recess RE1 and the second recess RE2 may be disposed between the through hole TH and the adjacent pixel P′.

According to an embodiment of the present disclosure, the first recess RE1 may be disposed between the first dam DM1 and the adjacent pixel P′. In more detail, the first recess RE1 may be disposed between the first dam DM1 and the second dam DM2.

According to an embodiment of the present disclosure, the second recess RE2 may be disposed between the second dam DM2 and the adjacent pixel P′.

The first recess RE1 and the second recess RE2 have concentric circle shapes and may be arranged to be spaced apart from each other. The first recess RE1 and the second recess RE2 may be spaced apart from each other with the second dam DM2 therebetween.

According to an embodiment of the present disclosure, as shown in FIG. 4, the first dam DM1, the first recess RE1, the second dam DM2, and the second recess RE2 are sequentially arranged.

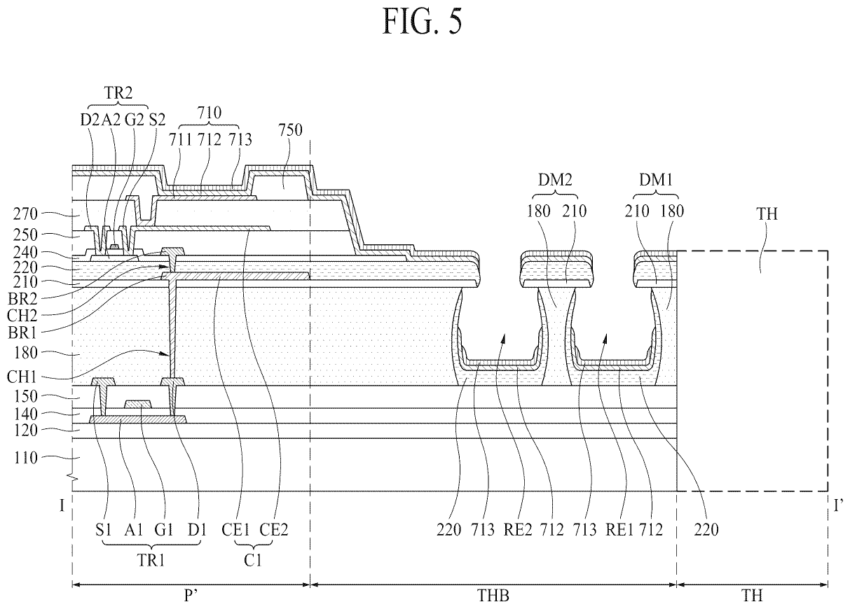

FIG. 5 is a cross-sectional view along a line I-I′ of FIG. 4 according to an embodiment of the present disclosure.

Referring to FIG. 5, the display apparatus 100 according to an embodiment of the present disclosure includes a substrate 110, a first buffer layer 120, a first thin film transistor TR1, a separation layer 180, and an inorganic insulating layer 210, a second thin film transistor TR2, and a display element 710.

In detail, the display apparatus 100 according to an embodiment of the present disclosure includes a first thin film transistor TR1 on a substrate 110, a separation layer 180 on the first thin film transistor TR1, an inorganic insulating layer 210 on the separation layer 180, a second thin film transistor TR2 on the inorganic insulating layer 210, and a display element 710 connected to one of the first thin film transistor TR1 and the second thin film transistor TR2.

The substrate 110 may include a display area AA and a non-display area IA surrounding the display area AA. The substrate 110 is a base layer and may include a plastic material or a glass material. As a plastic substrate, for example, a transparent or colored polyimide substrate may be used. The substrate 110 may be a flexible substrate or a rigid substrate.

A first buffer layer 120 may be disposed on the substrate 110. The first buffer layer 120 may be arranged to cover the entire surface of the substrate 110. The first buffer layer 120 may serve to block moisture or oxygen. For example, the first buffer layer 120 may include a single inorganic layer or a plurality of stacked inorganic layers. For example, the first buffer layer 120 may include at least one of a silicon oxide SiOx layer, a silicon nitride SiNx layer and a silicon oxynitride SiON layer.

The first buffer layer 120 may also be referred to as a lower buffer layer. The first buffer layer 120 may be omitted in some embodiments.

A first thin film transistor TR1 may be disposed on the first buffer layer 120.

The first thin film transistor TR1 includes a semiconductor layer A1, a gate electrode G1, a source electrode S1, and a drain electrode D1 disposed on the substrate 110 or on the first buffer layer 120. A gate insulating layer 140 may be disposed between the semiconductor layer A1 and the gate electrode G1.

In FIG. 5, a thin film transistor with a top gate structure in which the gate electrode G1 is disposed on top of the semiconductor layer A1 is shown, but an embodiment of the present disclosure is not limited thereto. As another example, the first thin film transistor TR1 may have a bottom gate structure in which the gate electrode G1 is disposed below the semiconductor layer A1 or a double gate structure in which gate electrodes G1 are disposed both on top of and below the semiconductor layer A1.

The semiconductor layer A1 may be disposed on the substrate 110 or on the first buffer layer 120. The semiconductor layer A1 may include a silicon based semiconductor material, an oxide based semiconductor material, or an organic based semiconductor material, and may have a single-layer structure or a multi-layer structure. A light shielding layer may be additionally disposed between the first buffer layer 120 and the substrate 110 to block external light incident on the semiconductor layer A1.

The gate insulating layer 140 insulates the semiconductor layer A1 from the gate electrode G1. The gate insulating layer 140 may be disposed on the entire surface of the substrate 110 to cover the semiconductor layer A1, or may be disposed only in the area where the semiconductor layer A1 and the gate electrode G1 overlap.

The gate insulating layer 140 may include, for example, at least one of a silicon oxide SiOx layer and a silicon nitride SiNx layer, or may have a multilayer structure including both the silicon oxide SiOx layer and the silicon nitride SiNx layer.

The gate electrode G1 is disposed on the gate insulating layer 140 to overlap at least a portion of the semiconductor layer A1. The gate electrode G1 is can be formed together with a gate line GL. According to an embodiment of the present disclosure, the gate electrode G1 may include at least one of molybdenum Mo, aluminum Al, chromium Cr, gold Au, titanium Ti, nickel Ni, neodymium Nd and copper Cu. The gate electrode G1 may have a single-layer structure or a multi-layer structure.

An interlayer insulating layer 150 may be disposed on the gate electrode G1. The interlayer insulating layer 150 may be formed on the entire surface of the substrate 110 to cover the gate electrode G1 and the gate insulating layer 140.

A source electrode S1 and a drain electrode D1 may be disposed on the interlayer insulating layer 150. For example, the source electrode S1 and the drain electrode D1 may be formed together with the data line DL or the driving power line PL.

Each of the source electrode S1 and the drain electrode D1 may be connected to the semiconductor layer A1 through an electrode contact hole penetrating the interlayer insulating layer 150 and the gate insulating layer 140. The source electrode S1 and the drain electrode D1 may include at least one of molybdenum Mo, aluminum Al, chromium Cr, gold Au, titanium Ti, nickel Ni, neodymium Nd, and copper Cu.

As described above, the first thin film transistor TR1 included in the pixel driving circuit PDC may be disposed on the substrate 110. In addition, the gate driver 320 disposed on the substrate 110 may include a thin film transistor that is the same with or similar to the first thin film transistor TR1 provided in the pixel P.

A separation layer 180 is disposed on the first thin film transistor TR1.

The separation layer 180 may be disposed, for example, on the entire surface of the substrate 110 to cover the first thin film transistor TR1. The separation layer 180 provides a flat surface over the first thin film transistor TR1. In addition, the separation layer 180 serves to separate the first thin film transistor TR1 and the second thin film transistor TR2 from each other.

The separation layer 180 may contains organic material. For example, the separation layer 180 may be an organic layer containing an organic material. The separation layer 180 may be made of organic material. According to an embodiment of the present disclosure, the separation layer 180 may be referred to as an organic separation layer.

According to an embodiment of the present disclosure, the separation layer 180 may include at least one of acryl resin, epoxy resin, phenolic resin, urethane resin, polyamide resin, polycarbonate resin and polyimide resin.

In order to sufficiently space the first thin film transistor TR1 and the second thin film transistor TR2 for electrical stability and to sufficiently flatten a surface over the first thin film transistor TR1, the separation layer 180 has a thickness of 1 to 4 μm. When the separation layer 180 has a thickness of 1 μm or more, the first thin film transistor TR1 and the second thin film transistor TR2 are sufficiently spaced apart to ensure mutual electrical stability. In addition, when the separation layer 180 has a thickness of 4 μm or less, the display apparatus 100 can be prevented from becoming thicker than necessary.

In detail, the separation layer 180 may have a thickness of 1 to 3 μm, and may also have a thickness of 1.5 to 2.5 μm.

According to an embodiment of the present disclosure, a portion of the separation layer 180 is removed to form recess RE1, RE2. The structure and method of forming the recess RE1, RE2 will be described later.

An inorganic insulating layer 210 may be disposed on the separation layer 180. The inorganic insulating layer 210 protects the upper part of the separation layer 180.

The inorganic insulating layer 210 includes an inorganic material. For example, the inorganic insulating layer 210 may include at least one of silicon oxide, aluminum oxide, titanium oxide, zirconium oxide, hafnium oxide, tantalum oxide, silicon nitride, aluminum nitride, zirconium nitride, titanium nitride, hafnium nitride, and tantalum nitride.

The inorganic insulating layer 210 has an etch rate different from an etch rate of the separation layer 180. According to an embodiment of the present disclosure, the etch rate of the separation layer 180 is greater than the etch rate of the inorganic insulating layer 210. In detail, the etch rate of the separation layer 180 is greater than the etch rate of the inorganic insulating layer 210 in the dry etch conditions. In addition, with respect to the etching solution for etching organic materials, the etch rate of the separation layer 180 is greater than the etch rate of the inorganic insulating layer 210.

According to an embodiment of the present disclosure, the etch rate of the separation layer 180 is designed to be greater than the etch rate of the inorganic insulating layer 210. Since the etch rate of the separation layer 180 is greater than the etch rate of the inorganic insulating layer 210, a jar-shaped recess RE1, RE2 may be formed.

According to an embodiment of the present disclosure, after patterning the inorganic insulating layer 210 and the separation layer 180, and then additional etching or over-etching the patterned separation layer 180, recess RE1, RE2 and dam portion DM1, DM2 may be formed. The structure and manufacturing method of the dam portion DM1, DM2 will be described later.

Referring to FIG. 5, a contact hole CH1 penetrating the inorganic insulating layer 210 and the separation layer 180 may be formed. The contact hole CH1 may be formed by patterning the inorganic insulating layer 210 and the separation layer 180.

A first bridge electrode BR1 may be formed on the inorganic insulating layer 210. The first bridge electrode BR1 may be connected to the first thin film transistor TR1 through the contact hole CH1. In detail, the first bridge electrode BR1 may be connected to the drain electrode D1 of the first thin film transistor TR1 through the contact hole CH1. However, an embodiment of the present disclosure is not limited thereto, and the first bridge electrode BR1 may be connected to the source electrode S1 of the first thin film transistor TR1 through the contact hole CH1.

In addition, a first capacitor electrode CE1 may be formed on the inorganic insulating layer 210. The first capacitor electrode CE1 is one electrode constituting the capacitor C1.

The first capacitor electrode CE1 may be formed integrally with the first bridge electrode BR1.

Referring to FIG. 5, a buffer layer 220 is disposed on the inorganic insulating layer 210, the first bridge electrode BR1, and the first capacitor electrode CE1. According to an embodiment of the present disclosure, the buffer layer 220 disposed on the inorganic insulating layer 210 may be referred to as a second buffer layer or an upper buffer layer.

The buffer layer 220 may serve to block moisture or oxygen. The buffer layer 220 may be arranged to cover the entire surface of the substrate 110.

The buffer layer 220 has insulating properties and may include an inorganic material. The buffer layer 220 may be made of a single inorganic layer or may include a plurality of stacked inorganic layers. For example, the buffer layer 220 may include at least one of silicon oxide SiOx, silicon nitride SiNx and silicon oxynitride SiON.

The second thin film transistor TR2 may be disposed on the buffer layer 220.

The second thin film transistor TR2 includes a semiconductor layer A2, a gate electrode G2, a source electrode S2, and a drain electrode D2 disposed on the buffer layer 220. A gate insulating layer 240 may be disposed between the semiconductor layer A2 and the gate electrode G2.

In FIG. 5, the second thin film transistor TR2 with a top gate structure, in which the gate electrode G2 is disposed on top of the semiconductor layer A2, is shown, but an embodiment of the present disclosure is not limited thereto. As another example, the second thin film transistor TR2 may have a bottom gate structure in which the gate electrode G2 is disposed below the semiconductor layer A2, or may have a double gate structure in which the gate electrodes G2 are disposed both on top of and below the semiconductor layer A2.

The semiconductor layer A2 is disposed on the buffer layer 220. The semiconductor layer A2 may include a silicon-based semiconductor material, an oxide-based semiconductor material, or an organic-based semiconductor material, and may have a single-layer structure or a multi-layer structure.

The gate insulating layer 240 insulates the semiconductor layer A2 from the gate electrode G2. The gate insulating layer 240 may be disposed on the entire surface of the substrate 110 to cover the semiconductor layer A2, or may be disposed only in the area where the semiconductor layer A2 and the gate electrode G2 overlap.

The gate insulating layer 240 may include, for example, at least one of silicon oxide SiOx and silicon nitride SiNx, and may have a single-layer structure or a multi-layer structure.

The gate electrode G2 is disposed on the gate insulating layer 240 to overlap at least a part of the semiconductor layer A2. The gate electrode G2 may be formed together with a gate line GL. According to an embodiment of the present disclosure, the gate electrode G2 may include at least one of molybdenum Mo, aluminum Al, chromium Cr, gold Au, titanium Ti, nickel Ni, neodymium Nd and copper Cu. The gate electrode G2 may have a single-layer structure or a multi-layer structure.

According to an embodiment of the present disclosure, the second bridge electrode BR2 may be disposed on the gate insulating layer 240.

Referring to FIG. 5, a contact hole CH2 may be formed to penetrate the gate insulating layer 240 and the buffer layer 220. The contact hole CH2 may be formed by patterning the gate insulating layer 240 and the buffer layer 220. The second bridge electrode BR2 may be disposed on the gate insulating layer 240. The second bridge electrode BR2 may be connected to the first bridge electrode BR1 on the inorganic insulating layer 210 through the contact hole CH2.

In addition, the second bridge electrode BR2 may be connected to the gate electrode G2 of the second thin film transistor TR2. In detail, the second bridge electrode BR2 may be connected to the gate electrode G2 of the second thin film transistor TR2 through a path different from the I-I′ cut surface shown in FIG. 5.

As described, the first bridge electrode BR1 may be connected to the drain electrode D1 of the first thin film transistor TR1 through the contact hole CH1. The second bridge electrode BR2 may be connected to the first bridge electrode BR1 and simultaneously connected to the gate electrode G2 of the second thin film transistor TR2. Thus, the drain electrode D1 of the first thin film transistor TR1 may be connected to the gate electrode G2 of the second thin film transistor TR2 by the first bridge electrode BR1 and the second bridge electrode BR2. As a result, as shown in the circuit diagram of FIG. 2, the first thin film transistor TR1 and the second thin film transistor TR2 may be electrically connected.

According to an embodiment of the present disclosure, by the first bridge electrode BR1 and the second bridge electrode BR2, the gate electrode G2 of the second thin film transistor TR2 may be connected to the drain electrode D1 of the first thin film transistor TR1. And, when the first thin film transistor TR1 is turned on, data voltage Vdata supplied through the data line DL can be supplied to the gate electrode G2 of the second thin film transistor TR2.

Referring to FIG. 5, an interlayer insulating film 250 may be disposed on the gate electrode G2 of the second thin film transistor TR2. The interlayer insulating film 250 may be disposed on the entire surface of the substrate 110 to cover the gate electrode G2 and the gate insulating layer 240.

A source electrode S2 and a drain electrode D2 may be disposed on the interlayer insulating film 250. The source electrode S2 and the drain electrode D2 may be formed together with, for example, the data line DL or the driving power line PL.

Each of the source electrode S2 and the drain electrode D2 may be connected to the semiconductor layer A2 through an electrode contact hole penetrating the interlayer insulating film 250 and the gate insulating layer 240. The source electrode S2 and the drain electrode D2 may include at least one of molybdenum Mo, aluminum Al, chromium Cr, gold Au, titanium Ti, nickel Ni, neodymium Nd and copper Cu.

In addition, a second capacitor electrode CE2 may be disposed on the interlayer insulating film 250. The second capacitor electrode CE2 may be connected to the source electrode S2 of the second thin film transistor TR2. According to an embodiment of the present disclosure, the second capacitor electrode CE2 may be formed integrally with the source electrode S2 of the second thin film transistor TR2.

The second capacitor electrode CE2 is disposed to overlap the first capacitor electrode CE1. The capacitor C1 of the pixel P is formed by the overlap of the first capacitor electrode CE1 and the second capacitor electrode CE2.

The capacitor C1 formed by overlapping the first capacitor electrode CE1 and the second capacitor electrode CE2 can act as a storage capacitor of the pixel P (see FIG. 2).

As described above, the second thin film transistor TR2 included in the pixel driving circuit PDC may be disposed on the separation layer 180 and the inorganic insulating layer 210. The gate driver 320 disposed on the substrate 110 may include a thin film transistor that is the same with or similar to the second thin film transistor TR2 provided in the pixel P.

According to an embodiment of the present disclosure, the first thin film transistor TR1 and the second thin film transistor TR2 are arranged in stacked state. When the first thin film transistor TR1 and the second thin film transistor TR2 are not arranged on a same plane but are stacked each other, the arrangement efficiency of the thin film transistors TR1 and TR2 can increase and the arrangement area can be reduced.

According to an embodiment of the present disclosure, as shown in FIG. 5, when the first thin film transistor TR1 and the second thin film transistor TR2 are arranged in a stacked state, a large number of thin film transistors can be arranged in a small area, and thus, the area of the capacitor C1 in the pixel P can be easily secured.

Since a high-resolution display apparatus has a large number of pixels P arranged in a limited area, a small area is allocated to each pixel P. According to an embodiment of the present disclosure, since thin film transistors can be efficiently arranged in a small area, the display apparatus 100 according to an embodiment of the present disclosure is advantageous for implementing a high-resolution display apparatus.

Referring to FIG. 5, a planarization layer 270 is disposed on the second thin film transistor TR2.

The planarization layer 270 is disposed on the entire surface of the substrate 110 to cover the thin film transistors TR1, TR2. The planarization layer 270 provides a planar surface over the thin film transistors TR1, TR2. The planarization layer 270 may include, for example, at least one of acryl resin, epoxy resin, phenolic resin, polyamide resin and polyimide resin.

The planarization layer 270 may include a pixel contact hole for exposing the source electrode or drain electrode of the driving thin film transistor provided in the pixel P.

A first electrode 711 of the display element 710 is disposed on the planarization layer 270. The first electrode 711 is connected to the source electrode S2 of the second thin film transistor TR2 through a contact hole formed in the planarization layer 270. Accordingly, the display element 710 may be connected to the second thin film transistor TR2.

In addition, as the first electrode 711 is connected to the source electrode S2 of the second thin film transistor TR2, the display element 710 may be connected to the capacitor C1.

The first electrode 711 of the display element 710 may be referred to as a pixel electrode or an anode.

According to an embodiment of the present disclosure, the first electrode 711 may include a metal material with high reflectivity. For example, the first electrode 711 may have a stacked structure of aluminum Al and titanium Ti (Ti/Al/Ti), a stacked structure of aluminum Al and indium tin oxide ITO (ITO/Al/ITO), silver palladium copper APC (Ag/Pd/Cu) alloy, or a multi-layer structure such as APC alloy and ITO laminated structure (ITO/APC/ITO). In addition, the first electrode 711 may include a layer containing one or more materials selected from silver Ag, aluminum Al, molybdenum Mo, gold Au, magnesium Mg, calcium Ca and barium Ba.

A bank layer 750 may be disposed at an edge of the first electrode 711. The bank layer 750 defines a light-emitting area of the display element 710. The bank layer 750 is disposed on the planarization layer 270 and defines an opening area or a light-emitting area of the pixel P disposed in the display area AA. This bank layer 750 may also be referred to as a pixel defining layer.

At the first electrode 711, the edge portions except for the middle portion of the first electrode 711 that overlap with the opening region of the pixel P may be covered by the bank layer 750.

An organic light emitting layer 712 is disposed on the first electrode 711. According to an embodiment of the present disclosure, the organic light emitting layer 712 may be disposed on the entire display area AA of the substrate 110 to cover the first electrode 711 and the bank layer 750.

The organic light emitting layer 712 may include, for example, two or more light emitting units vertically stacked to emit white light. According to an embodiment of the present disclosure, the organic light emitting layer 712 may include a first light emitting unit and a second light emitting unit for emitting white light by mixing a first light and a second light. Here, the first light emitting unit emits the first light and may include any one of a blue light emitting part, a green light emitting part, a red light emitting part, a yellow light emitting part, and a yellow green light emitting part. The second light emitting unit may include a light emitting part that emits second light having a complementary color relationship with the first light. When the organic light emitting layer 712 emits white light, the display apparatus 100 may further include a color filter layer (not shown). The color filter layer may be disposed in the direction in which light is emitted from the display element 710.

According to an embodiment of the present disclosure, the organic light emitting layer 712 may include any one of a blue light emitting part, a green light emitting part, and a red light emitting part for emitting light having a color corresponding to the color set in the pixel P.

A second electrode 713 is disposed on the organic light emitting layer 712. The second electrode 713 may also be referred to as a common electrode.

The second electrode 713 may contact the organic light emitting layer 712. The second electrode 713 may be disposed throughout the display area AA of the substrate 110 so as to commonly connect each organic light emitting layer 712 provided in each pixel P.

According to an embodiment of the present disclosure, the second electrode 713 may include a transparent conductive material or a transflective conductive material that can transmit light. When the second electrode 713 is formed of a transflective conductive material, the emission efficiency of light emitted from the light emitting device, which is display element 710, can be increased through a micro cavity structure. The transflective conductive material may include, for example, magnesium Mg, silver Ag, or an alloy of magnesium Mg and silver Ag.

Although not shown, a capping layer may be further disposed on the second electrode 713 to improve light emission efficiency by adjusting the refractive index of the layer through which the light emitted from the display element 710 passes. In addition, an encapsulation layer including at least one inorganic layer and at least one organic layer may be disposed on the second electrode 713.

By the first electrode 711, the organic light emitting layer 712, and the second electrode 713, the display element 710 is formed. The display element 710 shown in FIG. 5 is an organic light emitting diode OLED. Therefore, the display apparatus 100 according to an embodiment of the present disclosure can be referred to as being an organic light emitting display apparatus.

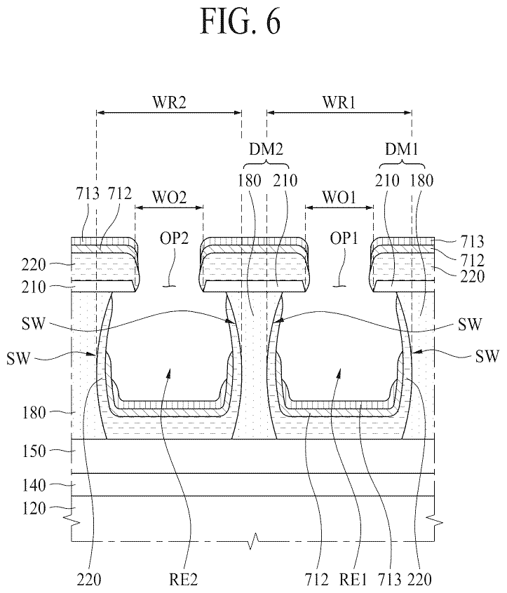

Hereinafter, the recess RE1, RE2 and dam portion DM1, DM2 of the display apparatus 100 according to an embodiment of the present disclosure will be described in more detail with reference to FIG. 6.

FIG. 6 is a partial enlarged view of the dam portion DM1, DM2 and the recess RE1, RE2 of FIG. 5 according to one embodiment.

Referring to FIGS. 4 and 5, the recess RE1, RE2 are disposed between the through hole TH and the adjacent pixel P′. Referring to FIGS. 5 and 6, the recess RE1, RE2 may be formed in the separation layer 180. By selectively removing the material constituting the separation layer 180, recess RE1, RE2 may be formed.

According to an embodiment of the present disclosure, it can be said that the separation layer 180 has recess RE1, RE2.

Referring to FIG. 6, the inorganic insulating layer 210 has an opening OP1, OP2, and the material constituting the separation layer 180 may be selectively removed from the bottom of the opening OP1, OP2 of the inorganic insulating layer 210 to form recess RE1, RE2.

The recess RE1, RE2 may be defined by the dam portion DM1, DM2 and the separation layer 180. In detail, the recess RE1, RE2 can be defined as an area or a space surrounded by dam portion DM1, DM2 and separation layer 180.

For example, the first recess RE1 may be defined by the first dam DM1 and the second dam DM2, and the second recess RE2 may be defined by the second dam DM2 and the separation layer 180.

Referring to FIGS. 5 and 6, the dam portion DM1, DM2 includes a separation layer 180 and an inorganic insulating layer 210 on the separation layer 180. The separation layer 180 and the inorganic insulating layer 210 may be patterned to form the dam portion DM1, DM2.

The separation layer 180 and the inorganic insulating layer 210 may be selectively patterned to form the recess RE1, RE2. For example, the separation layer 180 and the inorganic insulating layer 210 are patterned to form a through hole penetrating the inorganic insulating layer 210, and the separation layer 180 further etched to form the recess RE1, RE2. The recess RE1, RE2 may have an opening OP1, OP2 in a direction toward the inorganic insulating layer 210. The inorganic insulating layer 210 is not disposed in the opening OP1, OP2.

The opening OP1, OP2 may be defined by the inorganic insulating layer 210. In detail, opening OP1, OP2 may be formed by patterning the inorganic insulating layer 210. For example, the first opening OP1 of the first recess RE1 and the second opening OP2 of the second recess RE2 may be defined by inorganic insulating layers 210 that are patterned and spaced apart from each other.

According to an embodiment of the present disclosure, as shown in FIGS. 5 and 6, the separation layer 180 may have two or more recess RE1, RE2. Two or more recess RE1, RE2 may be spaced apart from each other with the second dam DM2 therebetween.

According to an embodiment of the present disclosure, the separation layer 180 has a greater etch rate than the etch rate of the inorganic insulating layer 210.

In detail, under a dry etch condition, the etch rate of the separation layer 180 may be greater than the etch rate of the inorganic insulating layer 210. In addition, with respect to the etching solution for etching organic materials, the etch rate of the separation layer 180 is greater than the etch rate of the inorganic insulating layer 210. Since the etch rate of the separation layer 180 is greater than the etch rate of the inorganic insulating layer 210, a jar-shaped recess RE1, RE2 can be formed as shown in FIG. 6.

Since the etch rate of the separation layer 180 is greater than the etch rate of the inorganic insulating layer 210, after a hole penetrating the separation layer 180 and the inorganic insulating layer 210 is formed, then an additional etching is performed to the separation layer 180. As a result, a width of the recess RE1, RE2 formed in the separation layer 180 may be formed larger than a width of the opening OP1, OP2 defined by the inorganic insulating film 210. Therefore, according to an embodiment of the present disclosure, a width of the recess RE1, RE2 is greater than a width of the opening OP1, OP2. In detail, the width WR1 of the first recess RE1 is greater than the width WO1 of the first opening OP1, and the width WR2 of the second recess RE2 is greater than the width WO1 of the first opening OP1.

According to an embodiment of the present disclosure, the width WR1, WR2 of the recess RE1, RE2 is defined as a width at the mid-height of the recess RE1, RE2, and the width WO1, WO2 of the opening OP1, OP2 is defined as a width measured at the bottom of the inorganic insulating layer 210.

Referring to FIGS. 5 and 6, an inorganic insulating layer 210 is disposed on a buffer layer 220. According to an embodiment of the present disclosure, the buffer layer 220 may also be disposed on a sidewall SW of the recess RE1, RE2. In detail, during the process of forming the buffer layer 220, the material for forming the buffer layer 220 is attached to the side walls SW of the recess RE1, RE2, and thus, the buffer layer 220 can also be formed at the side wall SW of the recess RE1, RE2.

The buffer layer 220 has insulating properties and may contain an inorganic material. For example, the buffer layer 220 may include at least one of silicon oxide SiOx, silicon nitride SiNx, and silicon oxynitride SiON. The buffer layer 220 containing an inorganic material has superior moisture and oxygen blocking properties compared to an organic material. As the buffer layer 220 is disposed on the side walls SW of the recess RE1, RE2 made of organic material, the penetration of moisture or oxygen through the side wall SW of the recess RE1, RE2 can be effectively prevented or at least reduced. As a result, the display apparatus 100 according to an embodiment of the present disclosure can have excellent moisture blocking properties and have excellent oxygen blocking properties.

According to an embodiment of the present disclosure, the display element 710 includes an organic light emitting layer 712. The organic light emitting layer 712, which comprises organic materials, is susceptible to moisture and oxygen, and the organic light emitting layer 712 itself and the interfaces of the organic light emitting layer 712 with other layers can be pathways for moisture or oxygen to migrate.

In particular, as shown in FIGS. 5 and 6, when a portion of the display panel 310 is cut to form a through hole TH, moisture or oxygen can easily penetrate through the cut surface. In particular, when the organic light emitting layer 712 is exposed on the cut surface, moisture or oxygen can easily penetrate through the organic light emitting layer 712 and the organic light emitting layer 712 may be easily damaged.

According to an embodiment of the present disclosure, the continuity of the organic light emitting layer 712 may be interrupted by the recess RE1, RE2. In detail, referring to FIGS. 5 and 6, the organic light emitting layer 712 is not continuously formed in a region of the recess RE1, RE2, and the continuity of the organic light emitting layer 712 may be broken. According to an embodiment of the present disclosure, the organic light emitting layer 712 loses continuity in the recess RE1, RE2.

For example, even though an organic light emitting material is deposited on the entire surface over the substrate 110 to form the organic light emitting layer 712, the organic light emitting layer 712 may not be formed continuously in the region of the jar-shaped recess RE1, RE2. As a result, the continuity of the organic light emitting layer 712 may be broken by the recess RE1, RE2.

When the continuity of the organic light emitting layer 712 is interrupted, the penetration path of moisture and oxygen is cut off, thereby preventing or suppressing the penetration of moisture and oxygen through the organic light emitting layer 712.

In particular, as shown in FIGS. 5 and 6, even though a portion of the display panel 310 is cut to form a through hole TH and a portion of the organic light emitting layer 712 is exposed, the continuity of the organic light emitting layer 712 is broken by the recess RE1, RE2, resultingly the penetration of moisture and oxygen can be easily prevented or suppressed.

According to an embodiment of the present disclosure, as shown in FIGS. 5 and 6, the organic light emitting layer 712 may be disposed on the bottom surface of the recess RE1, RE2. However, the organic light emitting layer 712 disposed on the bottom surface of the recess RE1, RE2 is not connected to the organic light emitting layer 712 disposed on the upper part of the buffer layer 220. As a result, the continuity of the organic light emitting layer 712 may be easily broken.

According to an embodiment of the present disclosure, the separation layer 180 may have a thickness of 1 to 4 μm. When the separation layer 180 has a thickness of 1 to 4 μm, the first thin film transistor TR1 and the second thin film transistor TR2 are sufficiently spaced apart to ensure mutual electrical stability, and at the same time, the display apparatus 100 can be prevented from becoming unnecessarily thick.

Due to the thickness of the separation layer 180, the recess RE1, RE2 may have a height of 1 μm or more. Due to the height of the recess RE1, RE2, it is impossible for the thin organic light emitting layer 712 to be connected between the bottom surface of the recess RE1, RE2 and the top of the buffer layer 220. As a result, the continuity of the organic light emitting layer 712 may be easily broken.

In addition, when the recess RE1, RE2 has a height of 1 μm or more, over-etching of the separation layer 180 for forming the recess RE1, RE2 can be easily accomplished. And accordingly, a width of the recess RE1, RE2 may be increased. The width of the recess RE1, RE2 may be more than twice the width of the opening OP1, OP2.

For example, the width WR1 of the first recess RE1 may be more than twice the width WO1 of the first opening OP1, and the width WR2 of the second recess RE2 may be more than twice the width WO2 of the second opening OP2.

According to an embodiment of the present disclosure, a through hole TH may be formed in the substrate 110. As already explained in the description of FIG. 4, the substrate 110 has a through hole TH, and the first thin film transistor TR1, the second thin film transistor TR2 and a display element 710 are not disposed in the through hole TH. The recess RE1, RE2 may be arranged to surround the through hole TH. In addition, the dam portion DM1, DM2 may also be arranged to surround the through hole TH.

According to an embodiment of the present disclosure, the first thin film transistor TR1, the second thin film transistor TR2 and the display element 710 are disposed on the substrate 110 to form a display panel 310, and then a portion of the panel 310 is cut or removed to form the through hole TH. The portion of the panel 310 is cut or removed with a shape of a through hole. As a result, the display panel 310 having a through hole TH can be manufactured.

The display apparatus 100 according to an embodiment of the present disclosure may further include an optical element 410 disposed to overlap the through hole TH formed in the substrate 110.

The optical element 410 may include, for example, any one of a camera, an infrared sensor, a proximity sensor, an illumination sensor, and a fingerprint sensor, or the like.

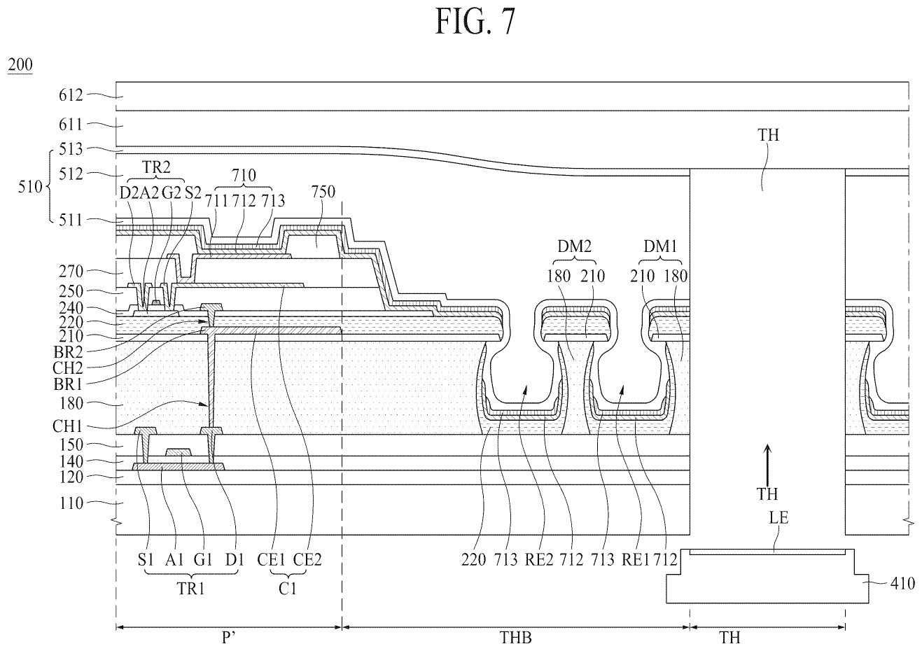

FIG. 7 is a partial cross-sectional view of a display apparatus 200 according to another embodiment of the present disclosure.

The display apparatus 200 according to another embodiment of the present disclosure has a through hole TH, which is disposed in the display area AA and penetrates the display panel 310. According to another embodiment of the present disclosure, various components or modules may be installed or arranged in the through hole TH. For example, an optical element 410 may be disposed in the through hole TH.

The display apparatus 200 according to another embodiment of the present disclosure may include an optical element 410 disposed overlapping the through hole TH. As the optical element 410, for example, at least one of a camera, an infrared sensor, a proximity sensor, an illumination sensor and a fingerprint sensor may be used.

FIG. 7 illustrates, for example, a configuration in which a camera as the optical element 410 is disposed in a through-hole TH.

When a camera is used as the optical element 410, the camera is located on the back of the display panel 310, and may be arranged so that the center of the camera lens LE coincides with the center of the through hole TH. When a camera is used as the optical element 410, the through hole TH may not have a shape of a complete circle.

For example, as shown in FIG. 7, the display apparatus 200 according to another embodiment of the present disclosure includes an encapsulation layer 510 and a cover window 612. The cover window 612 may be attached to the encapsulation layer 510 by using a light-transmissive adhesive layer 611.

The encapsulation layer 510 may be formed on the display element 710 over the substrate 110 to surround the display area AA. The encapsulation layer 510 may be disposed on the second electrode 713 of the display element 710. The encapsulation layer 510 protects the display element 710. In detail, the encapsulation layer 510 protects the thin film transistor TR1, TR2 and the organic light emitting layer 712 from external shock and prevents oxygen, moisture, or foreign particles from penetrating into the organic light emitting layer 712.

According to an embodiment of the present disclosure, the encapsulation layer 510 may include a plurality of inorganic encapsulation layers 511, 513 and at least one organic encapsulation layer 512 sandwiched between the plurality of inorganic encapsulation layers 511, 513.

For example, the encapsulation layer 510 includes a first inorganic encapsulation layer 511, an organic encapsulation layer 512 on the first inorganic encapsulation layer 511, and a second inorganic encapsulation layer 513 on the organic encapsulation layer 512.

The first inorganic encapsulation layer 511 and the second inorganic encapsulation layer 513 serve to block penetration of moisture or oxygen. Each of the first inorganic encapsulation layer 511 and the second inorganic encapsulation layer 513 may include, for example, at least one of silicon nitride, aluminum nitride, zirconium nitride, titanium nitride, hafnium nitride, tantalum nitride, silicon oxide, aluminum oxide, and titanium oxide. The first inorganic encapsulation layer 511 and the second inorganic encapsulation layer 513 may be formed by a chemical vapor deposition process or an atomic layer deposition process.

According to an embodiment of the present disclosure, the first inorganic encapsulation layer 511 may be disposed on the side wall SW of the recess RE1, RE2. In detail, the first inorganic encapsulation layer 511 may be disposed on the buffer layer 220 disposed on the side walls SW of the recess RE1, RE2.

The organic encapsulation layer 512 may have a structure sealed or encapsulated by the first inorganic encapsulation layer 511 and the second inorganic encapsulation layer 513. The organic encapsulation layer 512 may have a relatively large thickness compared to the first inorganic encapsulation layer 511 and the second inorganic encapsulation layer 513. The organic encapsulation layer 512 may include organic material.

Referring to FIG. 7, a light-transmitting adhesive layer 611 may be disposed on the encapsulation layer 510, and a cover window 612 may be disposed on the light-transmitting adhesive layer 611.

In the display apparatus 200 shown in FIG. 7, the through hole TH may be open only on the side facing optical element 410, and may be blocked by the cover window 612 on the upper side facing the user. Since most of the components of the display panel 310 have been removed through the through hole TH except for the cover window 612 on the front surface of the optical element 410, there may be no optical interference to the optical element 410.

Although not shown, in addition to the optical element 410, components or modules performing mechanical or physical functions may be disposed in the through hole TH. For example, a vibration means, a locking means, a rotation axis, or the like, may be disposed in the through hole TH.

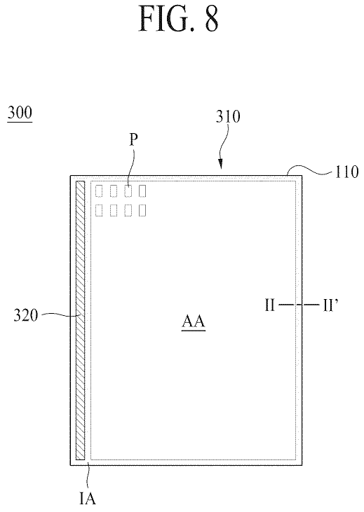

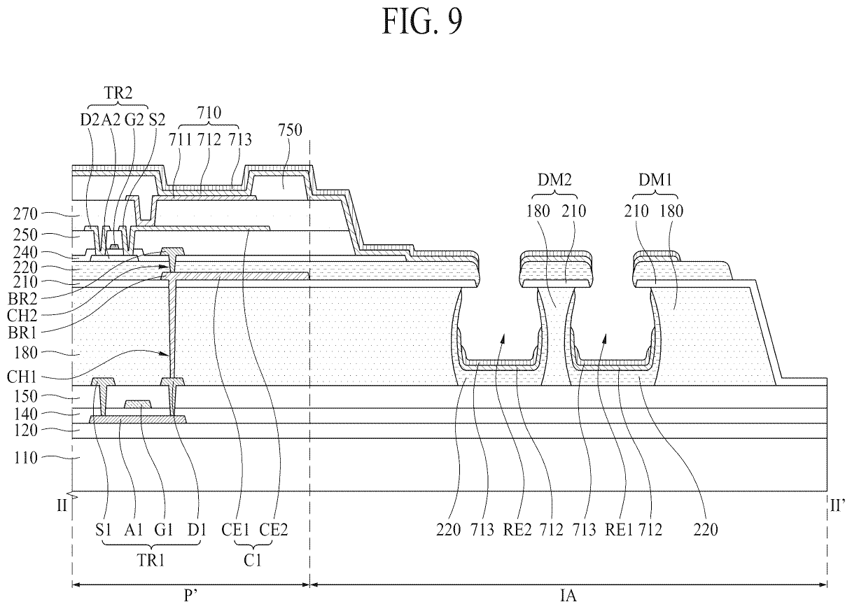

FIG. 8 is a schematic diagram of a display panel 310 of a display apparatus 300 according to another embodiment of the present disclosure, and FIG. 9 is a cross-sectional view along a line II-II′ of FIG. 8 according to an embodiment of the present disclosure.

According to the display apparatus 300 according to another embodiment of the present disclosure, the recess RE1, RE2 may be disposed along the edge of the substrate 110. Referring to FIGS. 8 and 9, the recess RE1, RE2 may be disposed in the non-display area IA surrounding the display area AA. The organic light emitting layer 712 may not disposed in the recess RE1, RE2, or the continuity of the organic light emitting layer 712 may be broken by the recess RE1, RE2.

As the recess RE1, RE2 are disposed in the non-display area IA corresponding to the edge of the substrate 110, the penetration path of moisture and oxygen from the outside into the display area AA of the display panel 310 becomes long. As a result, the display area AA can be effectively protected from moisture and oxygen.

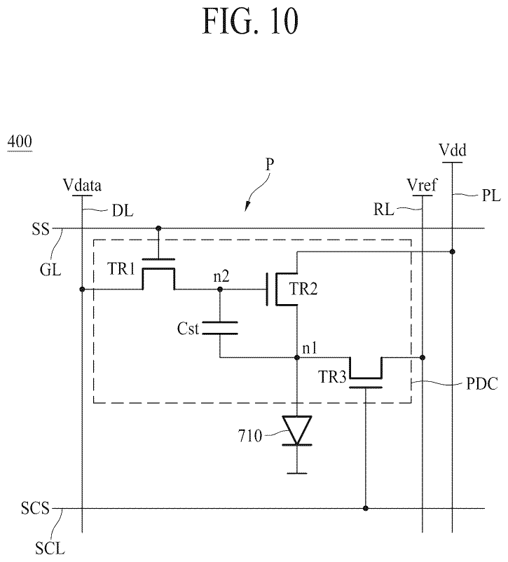

FIG. 10 is a circuit diagram of one pixel P of the display apparatus 400 according to another embodiment of the present disclosure. FIG. 10 is an equivalent circuit diagram of a pixel P of an organic light emitting display apparatus.

The pixel P of the display apparatus 400 shown in FIG. 10 includes an organic light emitting diode OLED, which is the display element 710, and a pixel driving circuit PDC that drives the display element 710. The display element 710 is connected to a pixel driving circuit PDC.

In the pixel P, signal lines DL, GL, PL, RL, and SCL that supply signals to the pixel driving circuit PDC are disposed.

A data voltage Vdata is supplied to the data line DL, a scan signal SS is supplied to the gate line GL, and a driving voltage Vdd for driving the pixel is supplied to the driving power line PL. The reference voltage Vref is supplied to the reference line RL, and the sensing control signal SCS is supplied to the sensing control line SCL.

The pixel driving circuit PDC, for example, includes a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1, and a third thin film transistor TR3 (sensing transistor) for sensing characteristics of the first thin film transistor TR1.

A storage capacitor Cst is located between the gate electrode of the second thin film transistor TR2 and the display element 710.

The first thin film transistor TR1 is turned on by the scan signal SS supplied to the gate line GL, and transmits the data voltage Vdata, which is supplied to the data line DL, to the gate electrode of the second thin film transistor TR2.

The third thin film transistor TR3 is connected to the first node n1 between the second thin film transistor TR2 and the display element 710, and connected to the reference line RL. The third thin film transistor TR3 is turned on or turned off by the sensing control signal SCS, and senses characteristics of the second thin film transistor TR2, which is a driving transistor, during the sensing period.

The second node n2, connected to the gate electrode of the second thin film transistor TR2, is connected to the first thin film transistor TR1. A storage capacitor Cst is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the storage capacitor Cst formed between the gate electrode and the source electrode of the second thin film transistor TR2.

When the second thin film transistor TR2 is turned on, current is supplied to the display element 710 through the second thin film transistor TR2 by the driving voltage Vdd that drives the pixel, and light is emitted from the display element 710.

According to another embodiment of the present disclosure, the first thin film transistor TR1, the second thin film transistor TR2, and the third thin film transistor TR3 may be disposed to be stacked.

In detail, at least one of the first thin film transistor TR1, the second thin film transistor TR2, and the third thin film transistor TR3 may be disposed under the separation layer 180, and at least one of the first thin film transistor TR1, the second thin film transistor TR2 and the third thin film transistor TR3 may be disposed on the separation layer 180.

For example, the first thin film transistor TR1 and the third thin film transistor TR3 may be disposed under the separation layer 180, and the second thin film transistor TR2 may be disposed above the separation layer 180. On the contrary, the first thin film transistor TR1 and the third thin film transistor TR3 may be disposed above the separation layer 180, and the second thin film transistor TR2 may be disposed under the separation layer 180. Alternatively, only the first thin film transistor TR1 may be disposed under the separation layer 180, and the second thin film transistor TR2 and the third thin film transistor TR3 may be disposed above the separation layer 180.

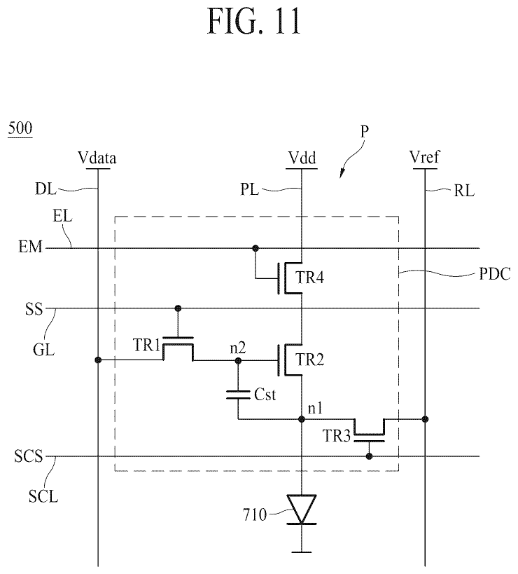

FIG. 11 is a circuit diagram of a pixel of a display apparatus 500 according to another embodiment of the present disclosure.

The pixel P of the display apparatus 500 shown in FIG. 11 includes an organic light emitting diode OLED, which is a display element 710, and a pixel driving circuit PDC that drives the display element 710. The display element 710 is connected to a pixel driving circuit PDC.

The pixel driving circuit PDC includes thin film transistors TR1, TR2, TR3, and TR4.

In the pixel P, signal lines DL, EL, GL, PL, SCL, and RL that supply signals to the pixel driving circuit PDC are disposed.

Compared to the pixel P in FIG. 10, the pixel P in FIG. 11 further includes an emission control line EL. An emission control signal EM is supplied to the emission control line EL.

In addition, compared to the pixel driving circuit PDC of FIG. 10, the pixel driving circuit PDC of FIG. 11 further includes a fourth thin film transistor TR4, which is a light emission control transistor for controlling the timing of light emission by controlling the second thin film transistor TR2.

A storage capacitor Cst is positioned between the gate electrode of the second thin film transistor TR2 and the display element 710.

The first thin film transistor TR1 is turned on by the scan signal SS supplied to the gate line GL, and transmits the data voltage Vdata, which is supplied to the data line DL, to the gate electrode of the second thin film transistor TR2.

The third thin film transistor TR3, which is connected to the reference line RL, is turned on or turned off by the sensing control signal SCS, and senses the characteristics of the second thin film transistor TR2, which is a driving transistor, during the sensing period.

The fourth thin film transistor TR4 transfers the driving voltage Vdd to the second thin film transistor TR2 or blocks the driving voltage Vdd according to the emission control signal EM. When the fourth thin film transistor TR4 is turned on, current is supplied to the second thin film transistor TR2, whereby light is emitted from the display element 710.

One or more of the thin film transistors TR1, TR2, TR3, and TR4 shown in FIG. 11 may be disposed under the separation layer 180, and the other one or more may be disposed above the separation layer 180.

The pixel driving circuit PDC according to another embodiment of the present disclosure may be formed in various structures other than those described above. The pixel driving circuit PDC may include, for example, five or more thin film transistors.

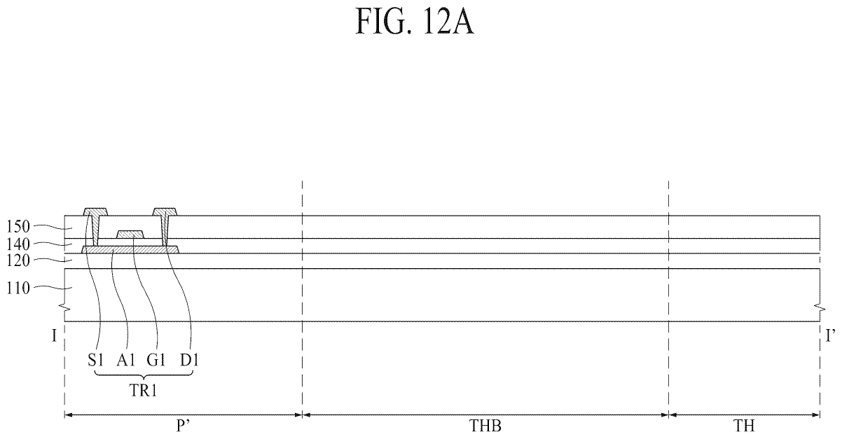

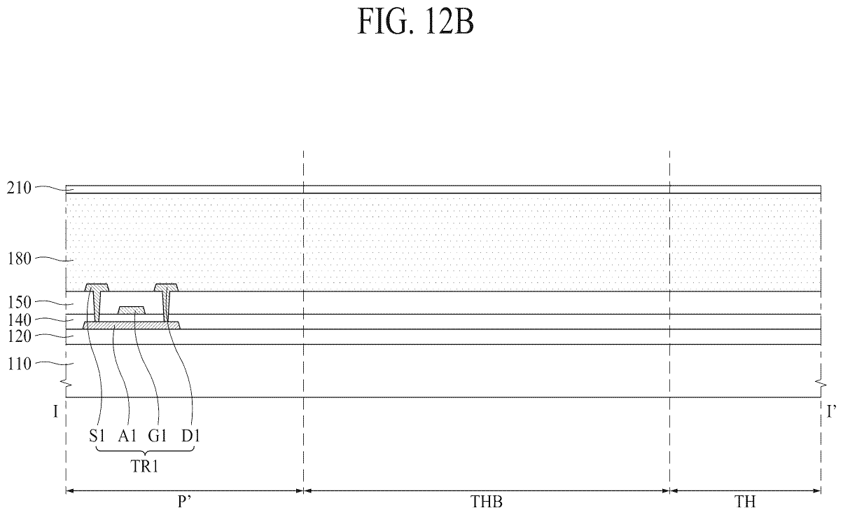

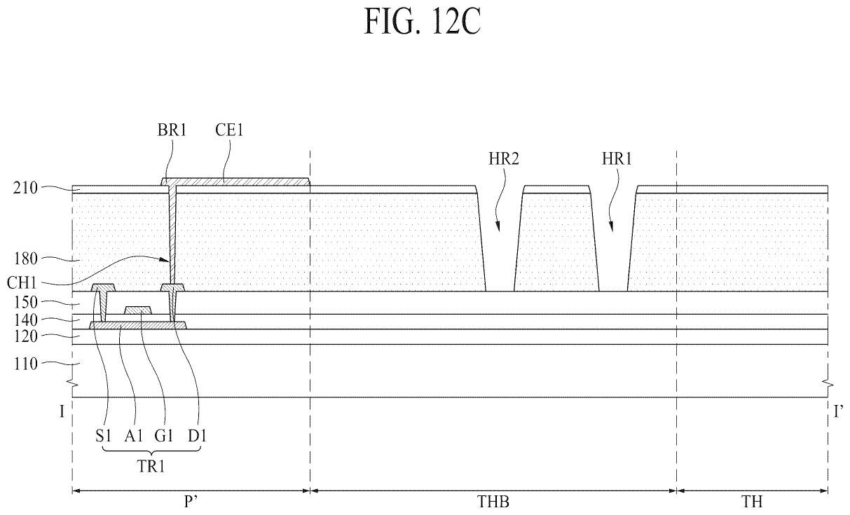

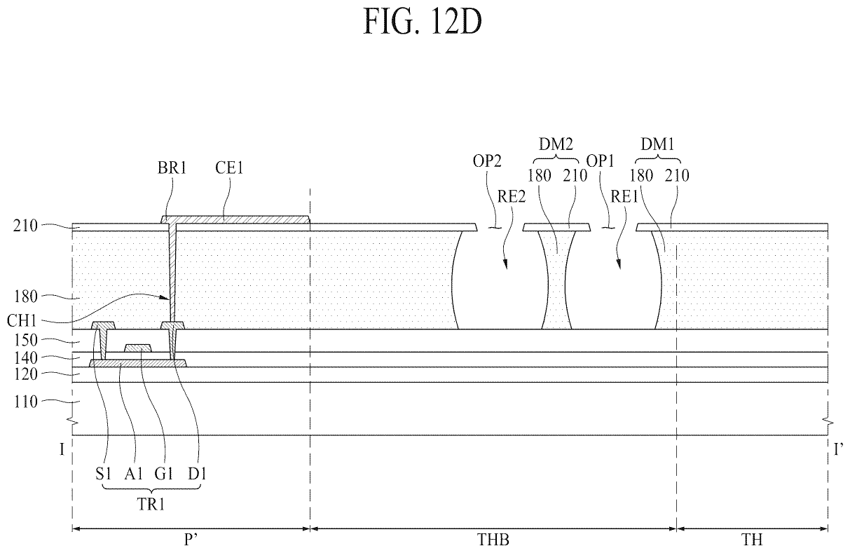

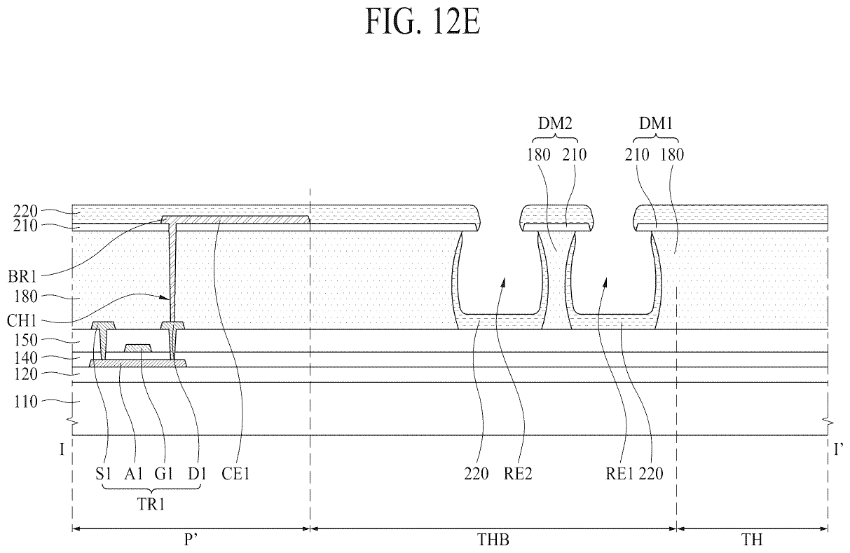

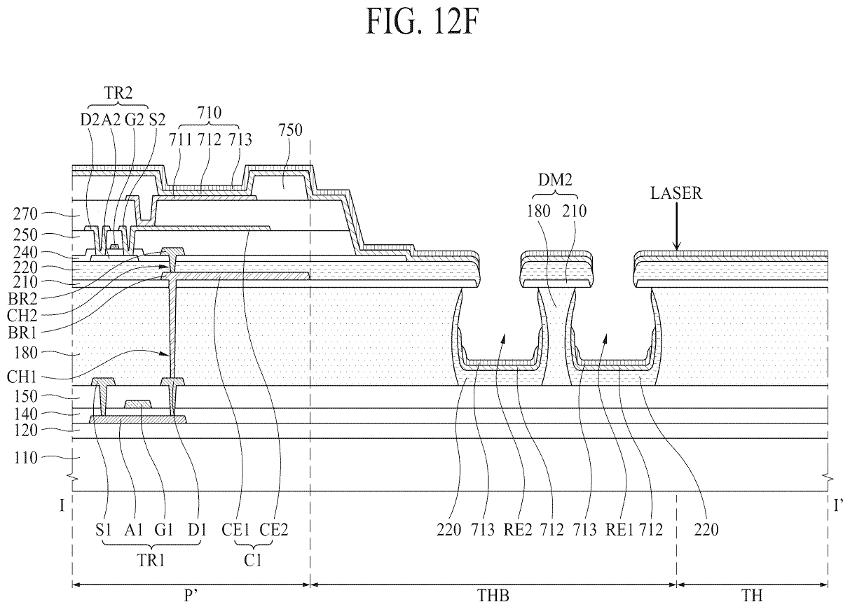

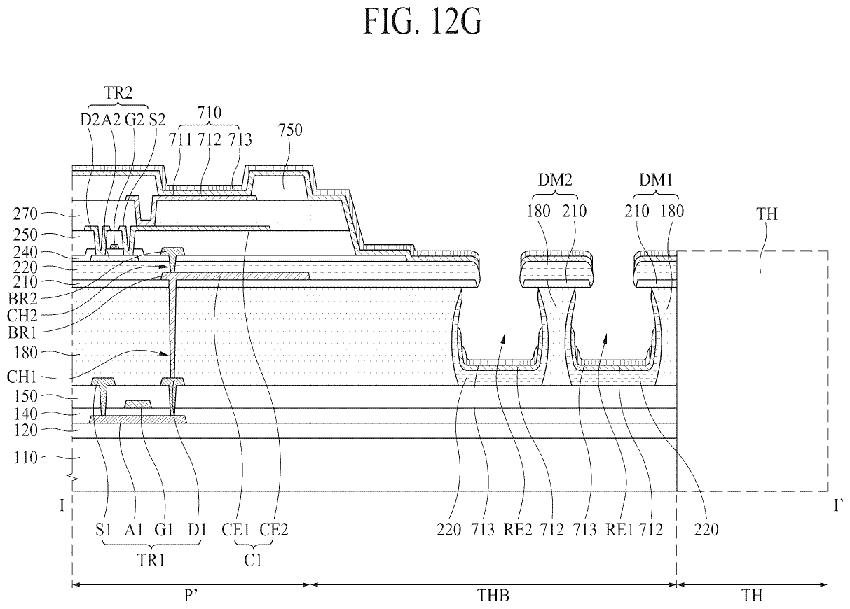

FIG. 12A to 12G are schematic diagrams of the manufacturing process of the display apparatus 100 according to an embodiment of the present disclosure.

Referring to FIG. 12A, a first thin film transistor TR1 is formed on the substrate 110. In detail, a first buffer layer 120 is formed on the substrate 110, a semiconductor layer A1 is formed on the first buffer layer 120, a gate insulating layer 140 is formed on the semiconductor layer A1, a gate electrode G1 is formed on the gate insulating layer 140, an interlayer insulating layer 150 is formed on the gate electrode G1, and a source electrode S1 and a drain electrode D1 are formed on the interlayer insulating layer 150.

Referring to FIG. 12B, a separation layer 180 including an organic material is formed on the first thin film transistor TR1. In addition, an inorganic insulating layer 210 is formed on the separation layer 180.

The separation layer 180 may comprise or may be made of organic materials. To form the separation layer 180, a material having an etch rate greater than an etch rate of the inorganic insulating layer 210 is used. The separation layer 180 has a higher etch rate than the etch rate of the inorganic insulating layer 210.

Referring to FIG. 12C, a portion of the inorganic insulating layer 210 and the separation layer 180 is removed to form a hole HR1, HR2 that passes through the inorganic insulating layer 210 and the separation layer 180. Optionally, the hole HR1, HR2 is formed along an edge of the substrate 110. At this time, a contact hole CH1 may be formed to connect the first thin film transistor TR1 and the second thin film transistor TR2. The first thin film transistor TR1 and the second thin film transistor TR2 may be electrically connected through the contact hole CH1 shown in FIG. 11C.

In addition, referring to FIG. 12C, a first bridge electrode BR1 may be formed on the inorganic insulating layer 210. The first bridge electrode BR1 is connected to the first thin film transistor TR1 through the contact hole CH1. The contact hole CH1 is filled or protected by the first bridge electrode BR1.

Referring to FIG. 12D, the hole HR1, HR2 formed in the separation layer 180 is expanded to form recess RE1, RE2 in the separation layer 180. Optionally, when the hole HR1, HR2 is formed along an edge of the substrate 110, the recess RE1, RE2 is also formed along the edge of the substrate 110.

According to an embodiment of the present disclosure, by patterning the inorganic insulating layer 210 and the separation layer 180, the hole HR1, HR2 passing through the inorganic insulating layer 210 and the separation layer 180 is formed (see FIG. 12C), and a part of the hole HR1, HR2 formed in the separation layer 180 is further etched to form the recess RE1, RE2 in the separation layer 180. The process of further etching the hole HR1, HR2 formed in the separation layer 180 may be referred to as an over-etch process for the separation layer 180. According to an embodiment of the present disclosure, a part of the hole HR1, HR2 formed in inorganic insulating layer 210 may become an opening OP1, OP2.

In the process of further etching the hole HR1, HR2 formed in the separation layer 180, the inorganic insulating layer 210 is not further etched or is hardly further etched. As a result, a width of the recess RE1, RE2 formed in the separation layer 180 may be made larger than a width of the opening OP1, OP2 defined by the inorganic insulating layer 210.

According to an embodiment of the present disclosure, the first opening OP1 of the first recess RE1 may be defined by the inorganic insulating layer 210 of the first dam DM1 and the inorganic insulating layer 210 of the second dam DM2, which are formed by patterning and spaced apart from each other. The second opening OP2 of the second recess RE2 may be defined by the inorganic insulating layer 210 of the second dam DM2 and the inorganic insulating layer 210 of the adjacent pixel P′. According to an embodiment of the present disclosure, the width WR1 of the first recess RE1 may be formed to be larger than the width WO1 of the first opening OP1, and the width WR2 of the second recess RE2 may be formed to be larger than the width WO2 of the second opening OP2.

Referring to FIG. 12E, a buffer layer 220 is formed on the inorganic insulating layer 210. The buffer layer 220 has insulating properties and may include an inorganic material.

According to an embodiment of the present disclosure, in the step of forming the buffer layer 220, the material for forming the buffer layer 220 is applied into the recess RE1, RE2 and disposed on the side wall SW of the recess RE1, RE2. As a result, as shown in FIG. 12E, a buffer layer 220 may be formed on the side wall SW of the recess RE1, RE2. As the buffer layer 220 is disposed on the side wall SW of the recess RE1, RE2, penetration of moisture or oxygen through the side wall SW of the recess RE1, RE2 can be easily prevented.

Referring to FIG. 12F, a second thin film transistor TR2 is formed on the buffer layer 220. In addition, a display element 710 is formed on the second thin film transistor TR2. The display element 710 may be connected to any one of the first thin film transistor TR1 and the second thin film transistor TR2. FIG. 12F shows a structure in which the display element 710 is connected to the second thin film transistor TR2.

According to an embodiment of the present disclosure, the display element 710 is an organic light emitting diode OLED including an organic light emitting layer 712. Forming the display element 710 includes forming an organic light emitting layer 712.

Referring to FIG. 12F, the continuity of the organic light emitting layer 712 is broken in the recess RE1, RE2. In detail, the organic light emitting layer 712 is not continuously formed in a region of the recess RE1, RE2, and the continuity of the organic light emitting layer 712 may be broken. When the continuity of the organic light emitting layer 712 is interrupted or broken, the penetration path of moisture and oxygen is cut off, thereby preventing or suppressing the penetration of moisture and oxygen through the organic light emitting layer 712.

Although not shown in FIG. 12F, an encapsulation layer 510 may be disposed on the display element 710.

After the display element 710 is formed, a through hole TH may be formed. According to an embodiment of the present disclosure, a through hole TH may be formed by cutting a portion of the display panel 310 into a hole shape. A laser may be used for cutting a portion of the display panel 310 to form the through hole TH.

Referring to FIG. 12G, a through hole TH is formed by cutting using a laser, thereby a display apparatus 100 according to an embodiment of the present disclosure is manufactured.

The present disclosure described above is not limited to the above-described embodiments and the accompanying drawings, and it is well known to those with ordinary knowledge that various substitutions, modifications, and changes are possible within the scope of the technical details of the present disclosure.

What is claimed is:

1. A display apparatus comprising:
a first thin film transistor on a substrate;
a separation layer on the first thin film transistor, the separation layer including an organic material;
an inorganic insulating layer on the separation layer;
a buffer layer on the inorganic insulating layer;
a second thin film transistor on the buffer layer; and
a display element connected to any one of the first thin film transistor and the second thin film transistor,
wherein the separation layer has a recess and the recess has an opening in a direction toward the inorganic insulating layer, and the inorganic insulating layer is not in the opening.

2. The display apparatus according to claim 1, wherein the separation layer has a higher etch rate than the inorganic insulating layer.

3. The display apparatus according to claim 1, wherein a width of the recess is greater than a width of the opening;
wherein the width of the recess is measured at a mid-height of the recess, and the width of the opening is measured at a bottom of the inorganic insulating layer.

4. The display apparatus according to claim 1, wherein a width of the recess is more than twice a width of the opening.

5. The display apparatus according to claim 1, wherein the separation layer has two or more recesses.

6. The display apparatus according to claim 1, wherein the buffer layer is on a side wall of the recess.

7. The display apparatus according to claim 1, wherein the display element includes an organic light emitting layer and the organic light emitting layer loses continuity in the recess.

8. The display apparatus according to claim 1, wherein the separation layer has a thickness of 1 μm to 4 μm.

9. The display apparatus according to claim 1, further comprising:
an optical element overlapping a through hole in the substrate,
wherein the first thin film transistor, the second thin film transistor, and the display element are not disposed in the through hole, and the recess surrounds the through hole.

10. The display apparatus according to claim 1, further comprising:
an encapsulation layer on the display element, the encapsulation layer comprising:
a first inorganic encapsulation layer;
an organic encapsulation layer on the first inorganic encapsulation layer; and
a second inorganic encapsulation layer on the organic encapsulation layer, wherein the first inorganic encapsulation layer is on the buffer layer disposed on a side wall of the recess.

11. The display apparatus according to claim 1, wherein the recess is along an edge of the substrate.

12. A method of manufacturing a display apparatus comprising:
forming a first thin film transistor on a substrate;
forming a separation layer containing an organic material on the first thin film transistor;
forming an inorganic insulating layer on the separation layer;
removing a portion of the inorganic insulating layer and a portion of the separation layer to form a hole passing through the inorganic insulating layer and the separation layer;
expanding the hole formed in the separation layer to form a recess in the separation layer;
forming a buffer layer on the inorganic insulating layer;
forming a second thin film transistor on the buffer layer; and
forming a display element connected to any one of the first thin film transistor and the second thin film transistor.

13. The method of manufacturing the display apparatus according to claim 12, wherein an etch rate of the separation layer is greater than an etch rate of the inorganic insulating layer.

14. The method of manufacturing the display apparatus according to claim 12, wherein forming the hole passing through the inorganic insulating layer and the separation layer further includes forming a contact hole connecting the first thin film transistor and the second thin film transistor.

15. The method of manufacturing the display apparatus according to claim 14, further comprising:
forming a first bridge electrode on the inorganic insulating layer,
wherein the first bridge electrode is connected to the first thin film transistor through the contact hole.

16. The method of manufacturing the display apparatus according to claim 12, wherein, in forming the buffer layer, a buffer layer forming material is disposed on a side wall of the recess.

17. The method of manufacturing the display apparatus according to claim 16, wherein forming the display element includes forming an organic light emitting layer, and the organic light emitting layer loses continuity in the recess.

18. The method of manufacturing the display apparatus according to claim 12, wherein the hole passing through the inorganic insulating layer and the separation layer is formed along an edge of the substrate such that the recess is formed along the edge of the substrate.
